(19) United States
(12) Patent Application Publication
(10) Pub. No.: US 2009/0026249 A1
(43) Pub. Date: Jan. 29, 2009

(54) METHOD FOR SOLDERING TWO COMPONENTS TOGETHER BY USING A SOLDER MATERIAL

(75) Inventors: Christophe Kopp, Fontanil Cornillon (FR); Jacqueline Bablet, Le Gua (FR); Jacques Raby, Grenoble (FR); Cyrille Rossat, Saint Etienne De Saint Geoirs (FR)

Correspondence Address: BURR & BROWN, PO BOX 7068, SYRACUSE, NY, 13261-7068, US

(73) Assignees: Commissariat A L'Energie Atomique, Paris (FR); Intexys, L'Union (FR)

(21) Appl. No.: 12/133,723

(22) Filed: Jun. 5, 2008

(30) Foreign Application Priority Data
Jul. 23, 2007 (FR) 07 05329

(51) Int. Cl. B23K 1/20; C23C 16/30

(52) U.S. Cl. 228/223; 228/203

(57) ABSTRACT

A method for soldering or hybridizing two components to each other by means of a solder material, including producing, on the opposite-facing surfaces of the components to be soldered or hybridized, a surface capable of being wetted by said solder material, this surface being produced on a first component which is in electrical contact with a metallic conductor, depositing an appropriate quantity of solder material capable of constituting a solder or hybridization pad on one of the wettability surfaces, depositing a flux material in liquid form, bringing the wettability surface of the other component into contact with the solder material thus deposited and raising the temperature until at least the melting temperature of the solder material is reached in order to ensure effective soldering or hybridization of the two components to each other due to the reflow effect.

### FIELD OF THE INVENTION

The present invention relates to the field of microelectronics and, more especially, techniques for the hybridization of two different components using interconnection bumps which are also referred to as “solder bumps”. The invention therefore relates to the general field of microcomponents, more conventionally referred to as a chips, but it also has applications for microsensors, microactuators such as Micro-Electro-Mechanical Systems (MEMS) and optoelectronic components of the semiconductor Vertical Cavity Surface Emitting Laser (VCSEL) type, etc.

Within the meaning of the invention, the term “component” is understood to be an electronic sensor such as a chip, a mounting structure for an electric or electronic circuit or a passive electrical component of the integrated-circuit lid type or even a sensor for characterizing a physical quantity.

### DESCRIPTION OF THE PRIOR ART

The microcomponents in question dealt with in the context of the present invention are conventionally deposited on a substrate of an appropriate nature, for example a semiconductor type substrate (monocrystalline silicon, sapphire, etc.) for electronic components.

These substrates have conductors, made of aluminum for example, that radiate from the microcomponent towards the periphery of the substrate in order to make it possible, above all, to process and analyze the signals that said component is expected to generate or even to control the functions that it incorporates, besides making it possible to provide the required electrical power supply for the component, if applicable.

One of the techniques which are widely used nowadays to assemble different components together is the hybridization technique using solder bumps which is referred to as “flip chip”. Briefly, this technology involves:
depositing an appropriate quantity of the material which constitutes the solder bump on one or more wettable surfaces located on one of the components to be assembled;
providing the other component to be hybridized with surfaces capable of being wetted by said solder material, said surfaces being located substantially vertically below the surfaces of said first component when the second component is mounted on the first component;
depositing a flux material in liquid form, said flux having a chemical deoxidation function and preventing reoxidation during soldering, with a thermal function making it possible to ensure heat transfer and a physical function making it possible to reduce the surface tension, thereby encouraging the formation of the actual solder bumps;
then bringing the wettability surface of the other component into contact with the solder material thus deposited;
and finally increasing the temperature until a temperature in excess of the melting temperature of the material that constitutes the bumps is reached in order to obtain fusion of the bumps until the desired result is achieved, namely hybridization of the first component on the second component, said bumps creating a mechanical and/or electrical bond between the wettable surfaces of each of the components, at least one of said wettable surfaces itself being connected to the conductors provided on the latter.

Thus, during the assembly process, the solder material that constitutes the bumps assumes a globular shape.

Soldering of indium, the material conventionally chosen to produce these bumps, on a wettable surface which itself is conventionally made of gold, requires the use of deoxidizing agents in liquid or gaseous form, the liquid flux also being referred to as “solder flux” in this case.

Generally speaking, these solder fluxes are inherently corrosive and after oxide reduction are also capable of attacking the actual solder metal.

Experience shows that this undesirable corrosion is made worse by two particular configurations:
a galvanic effect resulting from the use of a pair of metals having different electrochemical potentials in the presence of solder flux, the latter acting as an electrolyte;
the solder bumps and the flux remaining in contact for an excessively long time.

The galvanic effect can be explained as follows in relation to FIGS. 1 and 2 which schematically show flip chip hybridization in accordance with the prior art. These Figures show a first component 1 on which chip 2 is hybridized.

Component 1 comprises a host substrate 3, such as silicon, on which there are conductors 4, made of aluminum for example. Vertically above and below the hybridization areas there are, on substrate 3 and on the chip to be hybridized 2 respectively, wettable surfaces 7 and 8 which are also referred to as Under Bump Metallizations (UBM) and are typically made of gold.

At the same time, component 1 also comprises a plurality of external bonding pads 5. These pads actually consist of an electrically conductive surface which is capable of ensuring connections between the component to be hybridized and its external environment. Such a pad conventionally consists of a metallic surface onto which a wire, typically made of gold, may be thermocompressed.

During hybridization, after depositing the solder or braze material intended to constitute hybridization bump 6, deoxidizer 9 (FIG. 2) it spread all over component 1 and actually covers both external bonding pad 5 and hybridization bump 6. The material which constitutes the hybridization bump is usually made of indium, a tin-lead alloy or a lead-free alloy such as AgCuSn.

The gold layer of external bonding pad 5 is linked by an electrical connection consisting of aluminum conductor 4 to solder bump 6 so that, because of the presence of solder flux 9 which acts as an electrolyte, a closed electrical circuit is created, thereby causing an electrochemical phenomenon which results in reduction of the material which constitutes the hybridization bump in accordance with the well-known principle of a battery cell due to the different electrochemical potentials of the metals used. This being so, reduction of the material which constitutes the bump is observed and this results in it being dissolved, at least partially, in the solder flux and, consequently, impairment of the sought-after hybridization between chip 2 and component 1.

In order to overcome this drawback, suggestions were initially made to cover the external bonding pads with an insulating layer, for example a resin layer, in order to insulate the electrochemical circuit described above or to replace the gold of the external bonding pad by a metal having the same electrochemical potential as the material that constitutes the bump. However, both these solutions make the process of fabricating the host circuit, in this case the component, more complex, not only because of an additional stage which results in reduced fabrication yields, but also because of higher fabrication costs.

The use of cathodic protection has also been suggested:
by depositing a sacrificial anode based on the principle of bimetallic corrosion; a metal is connected to the metal to be protected and this added metal corrodes instead of the metallic structure, or;
by using the so-called impressed-current method which requires the use of a DC power source. In this case, the structure to be protected is connected to the negative terminal of a DC generator which is adjusted so as to mitigate corrosion activity affecting the structure to be protected.

In both cases, cathodic protection makes the fabrication process more complex and, in the latter case, makes the management of signal inputs and outputs more complicated.

It should, however, be emphasized that this technical problem which is inherent in the electrochemical consumption of the material that constitutes the hybridization bumps, is not actually critical if hybridization as such can be performed in a shorter time.

However, said hybridization operations tend to be systematically performed collectively in order to reduce fabrication costs. Thus, hybridization is performed using the collective reflow technique on hundreds or even thousands of components on a single host substrate. The corresponding hybridization sequence may then last several hours and, given this fact, the electrochemical corrosion or consumption phenomena described above can no longer be tolerated because they worsen over time.

The use of inert gas soldering has also been suggested. Using this method, inert gas can be used to ensure soldering. In this case, during the stage when the components are mounted on top of each other in order to ensure hybridization, the bumps and the metallic contacts are no longer electrically connected by an electrolyte. Known inert gases which are used include a N₂+HCOOH or N₂H₂ mixture. However, these gases have somewhat high activation temperatures, in excess of 200° C. and 350° C. respectively. These temperature rises can be disadvantageous, the reader being reminded that, for indium, a thermal soldering cycle with a brief peak at 170-180° C. is sufficient.

The object sought after by the present invention is to overcome these various technical problems without thereby making the hybridization process more complex.

### SUMMARY OF THE INVENTION

The invention relates to a method for soldering or hybridizing two components to each other by means of a solder material, at least one of said components, referred to hereinafter as the “first component”, comprising one or more metallic conductors linked to an equal number of external bonding pads.

This method involves:
Producing, on the opposite-facing surfaces of the components to be soldered or hybridized, a surface capable of being wetted by said solder material, this surface being produced on said first component which is in electrical contact with a metallic conductor;
depositing an appropriate quantity of solder material capable of constituting a solder or hybridization pad on one of said wettability surfaces;
depositing a flux material in liquid form having the following functions:
deoxidizing and limiting the reoxidation of said solder material after actually producing said soldered joint, transferring heat and reducing the surface tension;
bringing the wettability surface of the other component into contact with the solder material thus deposited;
then raising the temperature of the chamber in which the components to be soldered or hybridized are placed until at least the melting temperature of the solder material is reached in order to ensure effective soldering or hybridization of the two components to each other due to the reflow effect.

According to the invention, this method involves defining wettability areas which are differentiated in terms of the liquid solder flux so as to insulate, at least electrically, the volumes of flux which are in contact with those areas of said first component which receive the solder material and those defined by the external bonding pad or pads.

In other words, the invention involves creating an electrical discontinuity at the level of the solder flux between a specific area where the solder material is positioned and the external bonding pads, in order to prevent the electrochemical reaction which is inherent in the different redox potentials of the metals used.

According to one particular embodiment of the invention, an area which is not wettable by the solder flux is defined on said first component, for example by depositing a thin anti-wetting coating. This coating consists of SiOC or C₄F₈ for example.

This area which is slightly wettable or not wettable by the flux can be located vertically above the external pads or between those areas which receive the solder material and said external pads.

### DESCRIPTION OF THE DRAWINGS

The way in which the invention can be implemented and its resulting advantages will be made more readily understandable by the descriptions of the following embodiments, given merely by way of example, reference being made to the accompanying drawings.

As already stated,

FIGS. 1 and 2 are schematic representations of the hybridization principle according to the prior heart.

FIG. 3 is a side view of the hybridization method according to the invention in a first embodiment and

FIG. 4 is a top view.

FIGS. 5 and 6 are views similar to FIGS. 3 and 4 of a second embodiment of the invention.

### DETAILED DESCRIPTION OF THE PREFERRED EMBODIMENTS

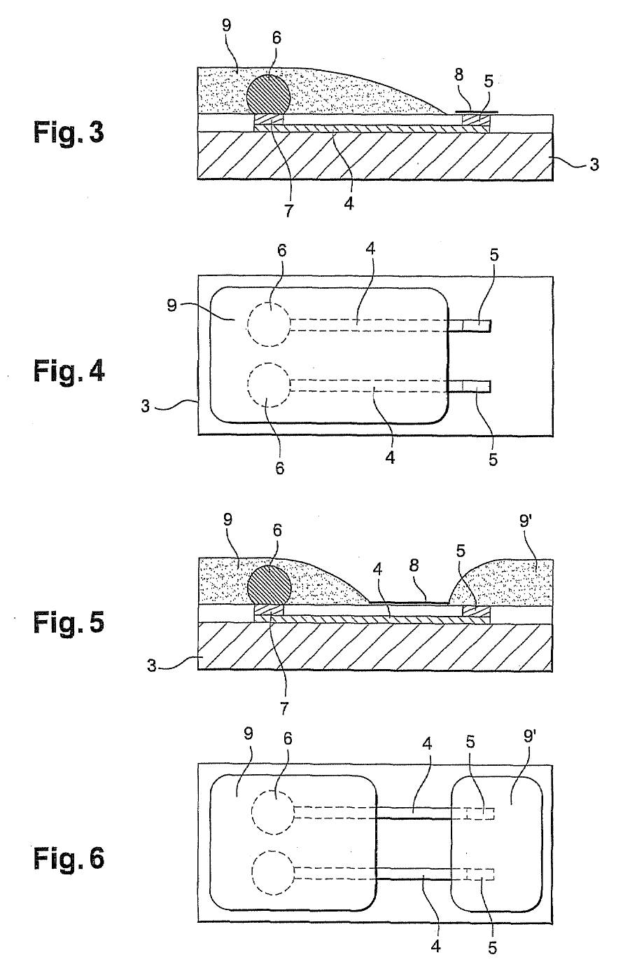

The hybridization method according to the invention is described more especially in relation to FIGS. 3 to 6.

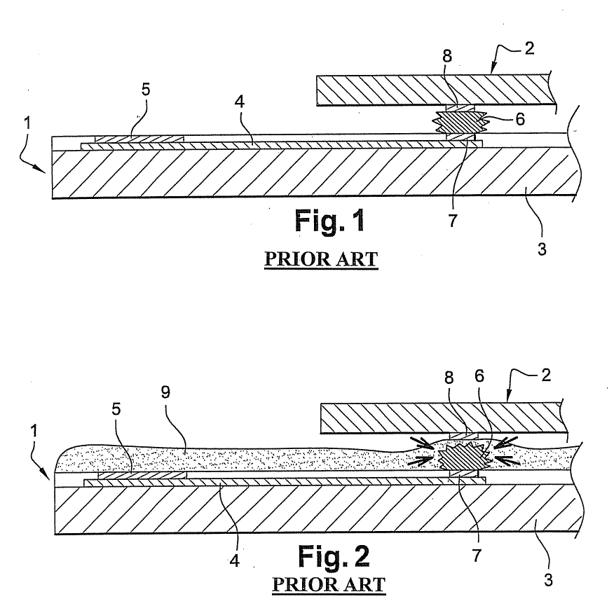

These show the hybridization of a chip 2 on an electronic component 1. As in the description of FIGS. 1 and 2, this component fundamentally comprises a substrate 3 which is also referred to as the host substrate. This is typically made of a semiconductor material, especially monocrystalline silicon. On this substrate 3 there are a number of conductors 4 designed, in this case, to allow the transmission of electric signals from chip 2 to the external environment with a view to processing them. These conductors are, for instance, made of aluminum and lead to one or more external bonding pads 5.

Such external bonding pads require the use of a localized layer which encourages electrical conduction and, in this case, consists of a gold wire.

The hybridization bumps which ensure connection and interfacing and are also referred to as “useful bumps” are typically made by depositing a quantity of solder material 6, especially indium, on a wettability area 7, which is also made of gold and positioned so that it is in contact with conductors 4 at the chosen hybridization location. In a known manner, chip 2 also comprises such a wettability area which is not represented in relation to FIGS. 3 to 6 because only the lower part of the component, i.e. the substrate, is shown.

The substrate complete with conductors can also be coated with a passivation layer made of SiO₂ or Si₃N₄.

According to a first aspect of the invention, a coating 8 which is not wettable by the solder flux used during the hybridization step is deposited on external bonding pad 5. This coating is thin, typically 10 to 500 nm, and consists, for example, of SiOC or C₄F₈.

This being so, when solder flux 9 is deposited, it does not cover non-wettable area 8 and consequently does not come into contact with external bonding pad 5.

In order to make sure that said solder flux 9 does not come into contact with external bonding pad 5, the coating which is not wettable by solder flux 8 has a surface area which is greater than that of external bonding pad 5.

This being so, there can no longer be a closed electric circuit consisting of external bonding pads 5, metallic conductors 4, hybridization bumps 6 and solder flux 9. Consequently, there can no longer be any electrochemical reaction whatsoever between these various elements where solder flux 9 would be capable of acting as an electrolyte which is associated with corrosion phenomena, with respect to the indium which constitutes said bumps, 6 as demonstrated in the description of the prior art.

It is not imperative to protect external bonding pad 5 by this coating which is slightly wettable or not wettable 8. The feature which is absolutely imperative is the absence of any electrical contact between the external bonding pad and the solder flux which is in contact with the hybridization bumps.

Thus, in a version of the invention shown in relation to FIGS. 5 and 6, it is apparent that the solder flux is divided into two portions 9 and 9′ which are independent of each other, said portion 9′ covering the external bonding pads 5. Given this assumption, non-wettability coating 8 is positioned between said external bonding pads 5 and the hybridization bumps 6.

The attraction of the method according to the invention is readily apparent.

Firstly, it eliminates any risk of corrosion of hybridization bumps 6 by eliminating the above-mentioned electrochemical reaction and does so regardless of the time that it takes to hybridize the components. Moreover, this method makes it possible to use a liquid solder or hybridization flux and, consequently, use a low hybridization temperature which is necessary if indium is used as a solder material.

What is more, it is also apparent that this hybridization method does not introduce any particular complications compared with methods according to the prior art and amounts to depositing a thin coating which is slightly wettable or not wettable by the solder flux.

This coating can be deposited, for example, by Plasma Enhanced Chemical Vapor Deposition (PECVD) by using a precursor, in this case Octamethylcyclotetrasiloxane (OMCTS) and a carrier gas such as argon or hydrogen.

Depending on the plasma power, pressure, initial precursor concentration and the plasma deposition time, one can control the thickness of the deposited layer and its SiOₓ₁C_{y1}H_{z1} stoichiometry. The formulation of material SiOₓ₁C_{y1}H_{z1} is such that 0.3≦x1≦0.4 and 0.15≦y1≦0.2 and 0.4≦z1≦0.55.

Obviously, this deposition method and the corresponding treatments can be extended to other types of siloxanes having a similar formulation such as, for example, tetraethylcyclotetrasiloxane (TNCTS).

This material can also be treated and surface converted into a material having the general formulation SiOₓ₂C_{y2}H_{z2} where x₂>>x₁, y₂<<y₁ and z₂<<z₁, or more simply SiOₓ, where x tends towards 2 in order, in particular, to increase its surface energy value, in particular its polar surface energy, and produce extremely good wettability by liquids (a contact angle of the order of 5° for water) and a very large increase in adhesion and cellular development (a generation time of 40 hours for unprocessed OMCTS compared with 20 hours for treated OMCTS).

The treatments used are either of the plasma type, namely a helium plasma or 0₂, SF₆+O₂, CHF₃+O₂ . . . ) oxygen plasmas or UV type plasmas in ambient air or in an oxygen enriched atmosphere.

This method therefore offers the possibility of easily localizing high surface-energy areas by treatment using either mechanical masks or optical masks. This being so, it is possible to localize droplets of various chemical substances, ranging from relatively non-viscous liquids (water, biological molecules or oil) to viscous liquids (adhesive, resin, paint) in a pattern determined by the mask and also to localize the adhesion of living cells (and the adsorption of biological molecules) in these areas.

The great attraction of the method according to the invention in simplifying the means used in order to ensure the hybridization of two components is readily apparent.

1. A method for soldering or hybridizing two components to each other by means of a solder material, at least one of said components, referred to hereinafter as the “first component”, comprising one or more metallic conductors linked to an equal number of external bonding pads, which involves:
producing, on the opposite-facing surfaces of the components to be soldered or hybridized, a surface capable of being wetted by said solder material, this surface being produced on said first component which is in electrical contact with a metallic conductor;
depositing an appropriate quantity of solder material capable of constituting a solder or hybridization pad on one of said wettability surfaces;
depositing a flux material in liquid form having the following functions: deoxidizing and limiting the reoxidation of said solder material after actually producing said soldered joint, transferring heat and reducing the surface tension;
bringing the wettability surface of the other component into contact with the solder material thus deposited;
then raising the temperature of the chamber in which the components to be soldered or hybridized are placed until at least the melting temperature of the solder material is reached in order to ensure effective soldering or hybridization of the two components to each other due to the reflow effect;
wherein it also involves defining, on said first component wettability areas which are differentiated in terms of the liquid solder flux so as to insulate, at least electrically, the volumes of flux which are in contact with those areas of said first component which receive the solder material and those defined by the external bonding pad or pads.

2. A method for soldering or hybridizing as claimed in claim 1, wherein the differentiated wettability areas are the result of depositing a thin anti-wetting coating on said first component.

3. A method for soldering or hybridizing as claimed in claim 2, wherein coating consists of SiOC or C₄F₈.

4. A method for soldering or hybridizing as claimed in claim 2, wherein coating is deposited by PECVD.

5. A method for soldering or hybridizing as claimed in any of claim 2, wherein coating is deposited vertically above external bonding pads.

6. A method for soldering or hybridizing as claimed in claim 2, wherein coating is deposited between the areas which receive solder material and external bonding pads.
